(19) United States
(12) Patent Application Publication
(10) Pub. No.: US 2008/0256415 A1
(43) Pub. Date: Oct. 16, 2008

(54) Error Detection/Correction Circuit as Well as Corresponding Method

(75) Inventors: Soenke Ostertun, Wedel (DE); Joachim Christoph Hans Garbe, Schenefeld (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/067,977

(22) PCT Filed: Sep. 19, 2006
(86) PCT No.: PCT/IB2006/053355

§ 371 Date: Mar. 26, 2008

(30) Foreign Application Priority Data
Sep. 27, 2005 (EP) 05108915.9
Sep. 19, 2006 (IB) PCT/IB2006/053355

(51) Int. Cl. H03M 13/05; G06F 11/08

(52) U.S. Cl. 714/758; 714/E11.03

(57) ABSTRACT

In order to provide an error detection/correction circuit (100; 100′) as well as a method for detecting and/or for correcting at least one error of at least one data word, said data word comprising—information in the form of at least one information bit or at least one pay load data bit, and—redundancy in the form of at least one check bit or at least one redundant bit, wherein the number of the one or more check bits or redundant bits being supplemented to the respective data word is optimized, in particular wherein at least one physical memory space can be used in an optimized way depending on the requirements of the application, it is proposed—to perform at least one first error correction scheme being assigned to at least one first data path (30; 30′), and—to perform at least one second error correction scheme—being assigned to at least one second data path (40; 40), and—being designed for increasing the information and/or the redundancy, in particular—for increasing the number of the one or more information bits or of the one or more pay load data bits and/or—for increasing the number of the one or more check bits or of the one or more redundant bits, of the respective data word being transmitted through the second data path (40; 40).

The present invention relates to an error detection/correction circuit according to the preamble of claim 1 as well as to an electronic memory component or memory module according to the preamble of claim 4.

The present invention further relates to a method for detecting and/or for correcting at least one error of at least one data word, said data word comprising
information in the form of at least one information bit or at least one payload data bit, and
redundancy in the form of at least one check bit or at least one redundant bit.

For increasing the reliability of memory blocks, error detection/correction circuits are frequently used. In order to ensure a safe correction of single bit errors in n payload data bits, additional redundant bits have to be stored, for example eight (or sixteen) reference bits require at least four (or five) redundant bits, i.e. approximately fifty percent (or 31 percent) additional storage space is required.

Because of this significant surcharge the number of redundant bits is kept as small as possible, thus normally defined by the smallest word length of the payload data. Without further increase of the redundancy, multi-bit error detection/recognition is possible only in rare, special cases of two-bit-combinations.

In security-relevant or safety-critical applications, the requirements of reliable read accesses of a memory are high. Various schemes to increase trustworthiness, and/or various schemes to reliably detect possible attacks are for example intermediate dummy read accesses without cell selection as described in prior art document WO 2004/049349 A2, or the use of a special code pattern forbidding physical data, with which all bits are in the same logical condition.

Such use of a special code pattern is described in prior art document WO 2004/046927 A1; in more detail, in prior art document WO 2004/046927 A1 an electronic memory component or memory module is disclosed, in which certain states of data representations are forbidden, and in which the occurrence of these states of data representations is interpreted as an attack of hackers.

In the case of particularly sensitive data records, for example of keys, the redundancy can further be increased, for example by additional C[yclic]R[edundancy]C[heck]s or by CRC check sums, and the data can be verified by the application. However, especially in the case of code execution such a procedure is not practicable. Additionally, as a matter of course additional check sums require also further memory.

General statements to the field of error detection/correction are given in prior art article “Avoid corruption in nonvolatile memory” by Christopher Leddy, to be found under the URL http://www.embedded.com/showArticle.jhtml?articleID=13100883.

A circuit for restricting data access is disclosed in prior art document US 2005/0066354 A1. However, the primary idea of this prior art document is to signal certain address regions of a memory module as privileged region.

Prior art document U.S. Pat. No. 5,623,504 refers to data with different degrees of error protection but the data are implemented as data blocks. The word width of the underlying data elements is always the same, i.e. the data elements have a uniform word size. The data blocks are regarded as a multi-dimensional field. The error correction takes place within this at least two-dimensional arrangement with differently strong algorithms, i.e. within the block there are positions with higher error correction and with lower error correction. However, the block structure is always maintained.

More particularly, in prior art document U.S. Pat. No. 5,623,504 a method is described as follows:

The uniformly sized data elements of a data block are distributed over an array of at least two dimensions. This array receives in at least two steps (one step per dimension) additional redundancy information.

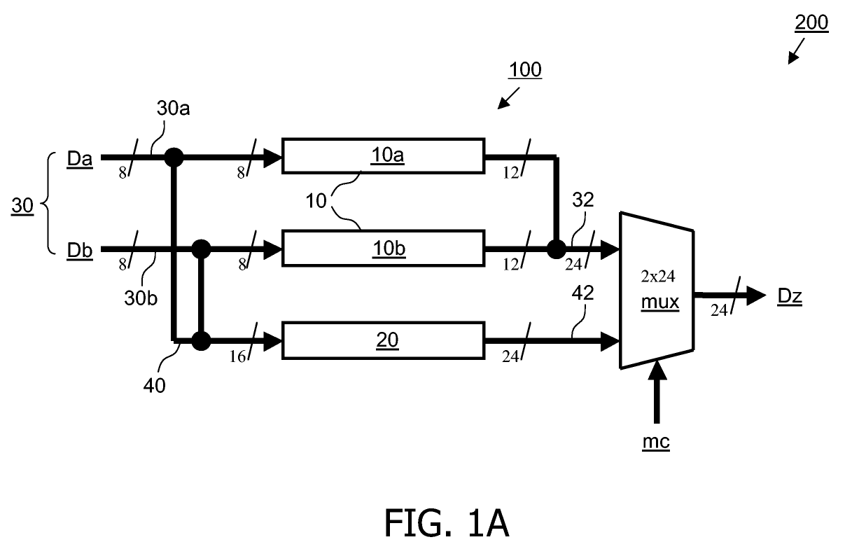

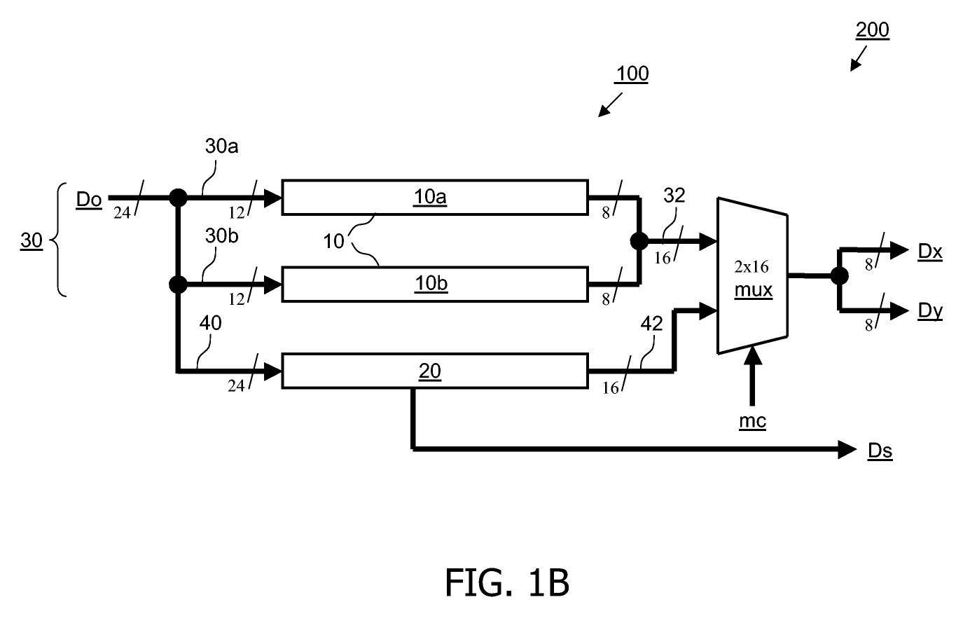

At computation of the additional redundancy information, the ratio of payload data to redundancy data can vary, for example in FIG. 1 of prior art document U.S. Pat. No. 5,623,504 five columns are coded in the ratio of eight to four and eight columns are coded in the ratio of ten to two. Only the total number of the data per column is fixed.

All in all, prior art document U.S. Pat. No. 5,623,504 describes a block-by-block coding, which is performed in several (, at least two) sequential steps. The error detection/correction with variable intensity refers only to certain positions within the data block.

Moreover, reference can be made to prior art article “Optimal Two-Level Unequal Error Control Codes for Computer Systems” by T. Ritthongpitak, M. Kitakami, and E. Fujiwara, IEEE, Proceedings of FTCS-26, 1996, 0731-3071/96, concerning data blocks with different levels of error protection at certain positions.

Regarding the discussion of this prior art article, reference can be made to the arguments as raised above in the discussion of prior art document U.S. Pat. No. 5,623,504.

Starting from the disadvantages and shortcomings as described above and taking the prior art as discussed into account, an object of the present invention is to further develop an error detection/correction circuit of the kind as described in the technical field, an electronic memory component or memory module of the kind as described in the technical field, as well as a method of the kind as described in the technical field in such way that the number of the one or more check bits or redundant bits being supplemented to the respective data word is optimized, in particular that at least one physical memory space can be used in an optimized way depending on the requirements of the application.

The object of the present invention is achieved by an error detection/correction circuit comprising the features of claim 1, by an electronic memory component or memory module comprising the features of claim 4 as well as by a method comprising the features of claim 7. Advantageous embodiments and expedient improvements of the present invention are disclosed in the respective dependent claims.

As mentioned in the chapter “Background and prior art” above, to ensure confidentiality data must be stored with redundancy. Thus, in many cases conventional memory components or conventional memory modules, in particular conventional memory blocks, are already equipped with error detection/correction circuits, which also use redundant data storage, for instance for reasons of lifetime.

A firmly selected error detection/correction pattern requires a certain quantity of additional storage space, whose size depends on the word length or word size of the payload data or of the one or more information bits. The present invention is based on the idea of performing at least two error detection/correction schemes.

According to a preferred embodiment of the present invention, both error detection/correction schemes are designed for
performing redundancy calculation, in particular for supplementing the respective data word being transmitted through the respective data path with the one or more check bits or with the one or more redundant bits, during at least one writing operation, and/or
for performing error detection, in particular for calculating at least one syndrome word, and/or for performing error correction, in particular for correcting the respective data word being transmitted through the respective data path, during at least one reading operation (in this context, a syndrome word permits conclusions on incorrect data bits and therefore is used for error detection and error correction of redundant data bits).

Moreover, according to a preferred embodiment of the present invention, the word length or word size of the respective data word can be, in particular variably, selected, for example depending on the application of the respective data word. The word length or word size of the respective data word is advantageously increased if the minimum word length or word size in certain cases is not required.

Thus, for example the one or more data words being transmitted through the second data path can have a different, in particular an increased, word length or word size in comparison to the one or more data words being transmitted through the first data path.

The one or more data words being transmitted through the second data path can in particular be correlated to the one or more data words being transmitted through the first data path when transmitted roughly in parallel and/or when transmitted roughly at the same time.

By increasing the word length or word size, for instance multi-bit error detection/recognition can be achieved because with increasing word length or word size the additional relative storage requirement becomes smaller.

For instance, if the word length or word size of the information data or payload data is increased from eight to sixteen bits, then two of the 8+4-bit physical words can be summarized to a 16+8-bit word. Effectively, thereby three additional data bits are won because for single-bit corrections, both for sixteen and for nineteen information bits or payload data bits only five redundant bits or check bits are required.

This additional information, i.e. in the example these three additional bits can advantageously be used
for system purposes, such as for markings, for example system flags, or
for increasing the redundancy (by enabling one or more additional check bits or redundant bits) and thus for increasing the data integrity.

Each data element being processed by the electronic memory component or memory module according to the present invention comprises at least two data words, wherein each data word is assigned to at least one memory area, said memory area being in particular assigned to at least one address range.

The use of two different error detection/correction schemes, in particular of two different error detection/correction patterns, within at least one memory component or memory module, in particular within at least one memory unit, makes it possible to use within different address ranges different word lengths or word sizes and thus different safety levels, if required.

Thus, for example the storage area for program code and secret keys can be provided with high redundancy, and a “more normal” data area can be used with the smaller word length or with the smaller word size. The definition of the different memory areas and/or of the error detection/correction scheme(s) being respectively used can advantageously be configured firmly.

Moreover, it is possible that the definition of the different memory areas and/or of the error detection/correction scheme(s) being respectively used is variably arranged in the application. However, according to an advantageous embodiment of the present invention, it is guaranteed that at least one read access is processed during the reading operation always with the same error detection/correction pattern as during the writing operation.

Since the present invention is based on the fact that the error detection/correction needs redundancy on the level of the smallest unit of data used during read operation(s) and write operation(s), for example bytes, using a large smallest unit for a specific memory area (address range), as proposed by a preferred embodiment of the present invention, allows to increase either the redundancy or the number of bits containing information without increasing the physical memory size.

Thus, with an appropriate or configurable error detection/correction scheme as provided by a preferred embodiment of the present invention, the physical memory can be used in an optimized way depending on the needs of the application: small and/or larger storage units can be used for “normal” data and “extended” data.

The extension can be used for higher security and confidentiality, for example enabling code execution in secure smart card controllers, as well as for storage of additional information, like system flags.

Unlike conventional schemes, where additional dummy read accesses as well as the selection of additionally stored C[yclic]R[edundancy]C[heck] sums require a complete read access and effectively increase the average access time, by a preferred embodiment of the present invention, being implemented for example as a configurable error detection/correction circuit arrangement, the access time of the memory component or memory module, in particular of the memory unit, is not influenced.

An essential feature of a preferred embodiment of the present invention is simultaneousness leading to the advantage that even temporally dissolved attacks can be reliably detected. In contrast thereto, because of the time offset with dummy-reading, temporally dissolved attacks cannot be reliably detected with conventional schemes if only the actual or genuine read access is disturbed.

Beside this, a preferred embodiment of the present invention comprises a high sensitivity with respect to attacks concerning some few bits. In contrast thereto, conventional code patterns, which forbid physically identical bits in a whole data word, by definition can only recognize attacks manipulating the whole data word.

Furthermore, the teaching of the present invention leads to the advantage that for its implementation and/or for its application no additional memory, such as for C[yclic]R[edundancy]C[heck] sums, is required.

Finally, the present invention comprises the advantageous feature that it can be combined with conventional schemes, for example
with schemes for increasing trustworthiness of security relevant or safety critical data and/or
with schemes for reliably detecting possible attacks.

The combination of the present invention with conventional schemes is even meaningful.

The procedure of signalizing different address regions (as described in prior art document US 2005/0066354 A1; cf. chapter “Background and prior art” above) can advantageously be used in combination with the present invention in order to decide in which area(s) memory access takes place.

However, in contrast to prior art document US 2005/0066354 A1 which focuses on signalling different address regions, the focus of the present invention is data coding as such. An exemplary application of the present invention is to use different error detections/corrections within different ranges of the memory.

According to a preferred embodiment of the present invention (and in contrast to prior art document U.S. Pat. No. 5,623,504 as cited in the chapter “Background and prior art” above), the logical length or logical size of data word(s) can be variably selected, for example depending upon application and/or depending upon storage area, whereas the physical width of the data word(s) of the memory is firmly given by summarizing several physical words or not.

For example, with twelve physical bits
about eight utilizable bits, in particular information bits or payload data bits, and
about four check bits or redundant bits can be realized, permitting a one-bit error correction.

By increasing the word length or word size, in particular by summarizing two physical words and by adjusting the error detection/correction scheme, i.e. by using the second error detection/correction scheme, the 24 bits (of the example) can be used
either for increasing the redundancy (for one-bit error correction of sixteen utilizable bits usually only five redundant bits are required)
or for increasing the number of the one or more information bits or payload data bits

(in the present example, for example nineteen information bits or payload data bits plus five check bits or redundant bits).

A preferred embodiment of the present invention concerns a simple, one-dimensional error correction, being not sequentially performed by several steps.

The subject-matter of a preferred embodiment of the present invention is to protect the smallest unit being practicably usable in the system according to the present invention, in particular the smallest unit being practicably usable in the electronic memory module or memory component as described above. Such smallest unit can for example be an eight-bit word or a sixteen-bit word.

According to this preferred embodiment of the present invention, the required number of check bits or redundant bits for the memory (in the present example four additional bits) results from the smallest unit being practicably usable (in the example eight bits).

In case a bigger unit (for example a sixteen-bit unit) can be chosen as smallest unit in at least one certain memory area or storage area (or if applicable also in the whole memory of a certain application—there are no fundamental limitations, only the administration effort within the application sets boundaries), the resulting additional redundant bits being physically available in the memory/storage can be used for different purposes, for instance
for increasing the redundancy and therefore the possibility of error detection and/or error correction, and/or
for storing additional information as described above.

In contrast thereto, prior art document U.S. Pat. No. 5,623,504 concerns the protection of data blocks with fixed configuration.

In general, the present invention can be applied to integrated circuits, such as chip cards or smart cards. Chip cards or smart cards comprise different memory areas, for example
random access memory (so-called RAM),
read only memory (so-called ROM),
electrically erasable and programmable read only memory (so-called EEPROM),
flash memory, etc.

In particular in security relevant or safety critical applications, such as money cards, the memory types of EEPROM or of flash memory are usually not applicable for the storage of program code because the data integrity can not be sufficiently ensured. The advantage of a possible code actualization in the finished product is lapsed thereby because program code can only be put down in the ROM when using conventional storage types.

The option by the present invention to increase redundancy, optionally in combination with one or more conventional error detection/correction schemes, enables to increase the data security in a dimension, which is equivalent to the data security of the ROM.

If a clear separation of different data words, in particular of data words with different safety necessities or security requirements, such as program codes, code areas or keys and “normal” data words or “normal” data areas is permitted (for example by software), the increase of data security is not required to be performed without the smaller word length or without the smaller word size in the “normal” data word or data area.

Thus, a preferred embodiment of the present invention provides multiple levels of error detection/correction by performing the at least two error detection/correction schemes, in particular by performing
the first, in particular normal, error detection/correction scheme, and
the second, in particular extended, error detection/correction scheme.

Especially memory components or memory modules, for example memory units, offering a small word length or word size for reasons of compatibility can profit from increasing word length or word size as described above, if the application of the memory components or memory modules, for example of the memory units, actually does not need the small word length or word size.

According to a preferred embodiment of the present invention, at least one configurable error detection/correction circuit arrangement is provided
for executing at least one security relevant data word, in particular for executing safe codes, from at least one memory block or memory module and/or
for storing additional information.

The present invention finally relates to the use of at least one error detection/correction circuit as described above and/or of at least one memory component or memory module as described above and/or of the method as described above when processing at least one security-relevant or safety-critical application, in particular in at least one chip card or smart card, for example in at least one embedded security controller.

Thus, a preferred embodiment of the present invention relates to the field of security-relevant or safety-critical applications where the confidentiality of data read-outs of memory components or memory modules, in particular of memory blocks, is very critical.

The present invention can be used especially in case of code execution, where it is required to be able to detect attacks which are trying to manipulate the read operation.

As already discussed above, there are several options to embody as well as to improve the teaching of the present invention in an advantageous manner. To this aim, reference is made to the claims respectively dependent on claim 1, on claim 4 and on claim 7; further improvements, features and advantages of the present invention are explained below in more detail with reference to two preferred embodiments by way of example and to the accompanying drawings where

FIG. 1A shows in the form of a schematic block diagram the part of a first embodiment of an error detection/correction circuit according to the present invention which is involved in the programming or writing operation;

FIG. 1B shows in the form of a schematic block diagram the part of a first embodiment of an error detection/correction circuit according to the present invention which is involved in the reading operation;

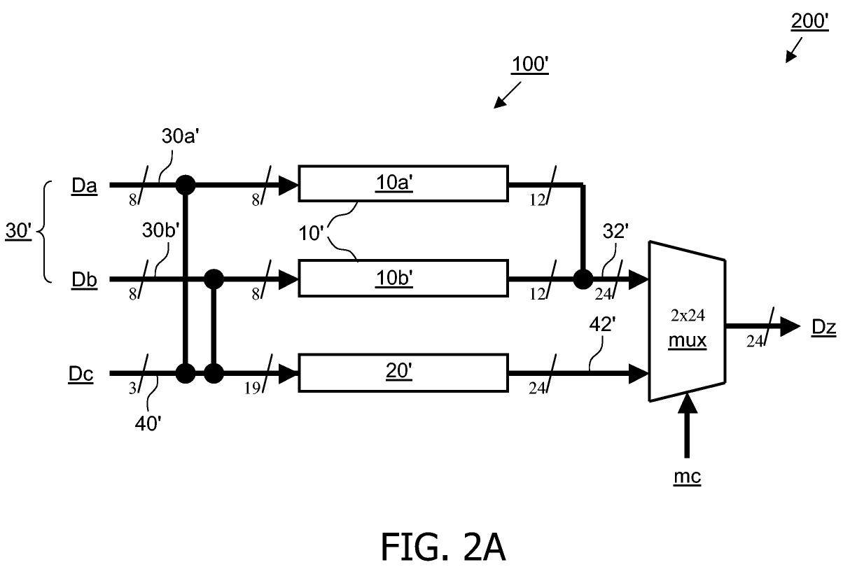

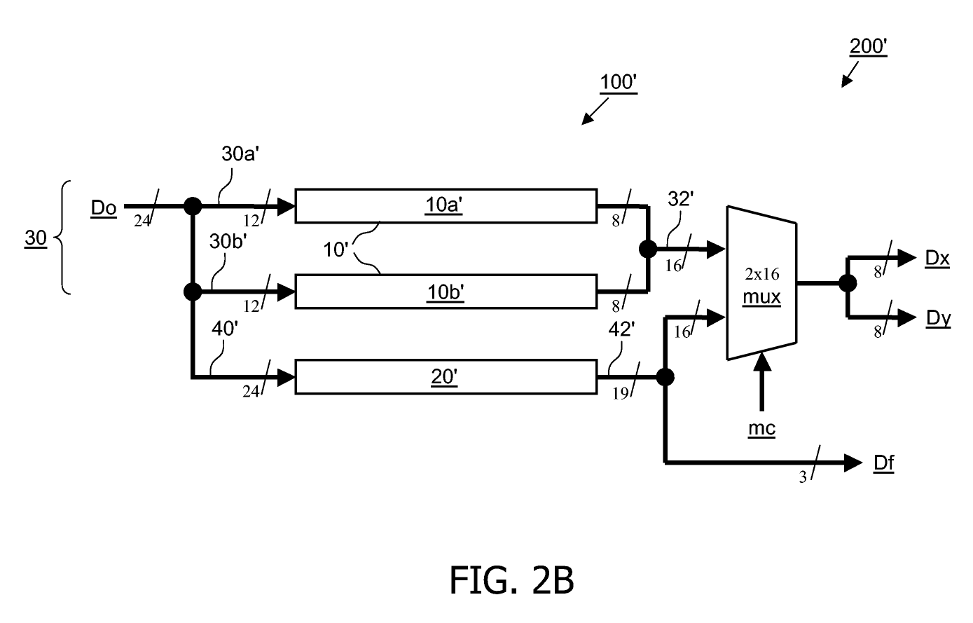

FIG. 2A shows in the form of a schematic block diagram the part of a second embodiment of an error detection/correction circuit according to the present invention which is involved in the programming or writing operation; and

FIG. 2B shows in the form of a schematic block diagram the part of a second embodiment of an error detection/correction circuit according to the present invention which is involved in the reading operation.

The same reference numerals are used for corresponding parts in FIG. 1A to 2B.

In order to avoid unnecessary repetitions, the following description regarding the embodiments, characteristics and advantages of the present invention relates (unless stated otherwise)
to the first embodiment of the electronic memory component or memory module 200 according to the present invention comprising the first embodiment of the error detection/correction circuit arrangement 100 according to the present invention (cf. FIGS. 1A, 1B), as well as
to the second embodiment of the electronic memory component or memory module 200′ according to the present invention comprising the second embodiment of the error detection/correction circuit arrangement 100′ according to the present invention (cf. FIGS. 2A, 2B),

all embodiments 200, 100 or 200′, 100′ being operated in compliance with the method of the present invention.

The first embodiment of the memory component or memory module 200 comprising the first embodiment of the error detection/correction circuit 100 (cf. FIGS. 1A, 1B) and the second embodiment of the memory component or memory module 200′ comprising the second embodiment of the error detection/correction circuit 100′ (cf. FIGS. 2A, 2B) can be implemented by an identical configuration.

However, in FIGS. 1A, 1B a first embodiment of an application of the present invention, namely increasing the redundancy, is depicted, whereas in FIGS. 2A, 2B a second embodiment of an application of the present invention, namely increasing the information, is depicted. Thus, in the following it is described in detail by way of two preferred embodiments how the present invention can be built and used.

In order to enable two different detection/correction patterns, the error detection/correction circuit 100 or 100′ according to the present invention comprises two processing modules 10, 20 or 10′, 20′ being assigned to two corresponding separate data paths 30, 40 or 30′, 40′.

The first processing module 10 or 10′ is assigned to the first data path 30 or 30′, more specifically,
a first processing part 10a or 10a′ of the first processing module 10 or 10′ is assigned to a first part 30a or 30a′ of the first data path 30 or 30′, and
a second processing part 10b or 10b′ is assigned to a second part 30b or 30b′ of the first data path 30 or 30′.

The second processing module 20 or 20′ is assigned to the second data path 40 or 40′.

The memory component or memory module 200 or 200′ further comprises a data bus and a multiplexer module or multiplexer unit (-->reference numeral mux) for interconnecting the first processing module 10 or 10′ and the second processing module 20 or 20′ with the data bus.

More specifically, the multiplexer unit mux provides the data bus
with an output signal 32 or 32′ of the first data path 30 or 30′, and/or
with an output signal 42 or 42′ of the second data path 40 or 40′,

depending on a check signal or monitoring signal, namely depending on a mode control signal (-->reference numeral mc).

The memory component or memory module 200 or 200′ can be configured as
an E[rasable]P[rogrammable]R[ead]O[nly]M[emory] unit,
an

E[lectrically]E[rasable]P[rogrammable]R[ead]O[nly]M[emory] unit,
a flash memory unit,
a R[ead]O[nly]M[emory] unit, or
as a R[andom]A[ccess]M[emory] unit.

Each processing module 10, 20 or 10′, 20′ is advantageously
implemented as an E[rror]C[orrection]C[ircuit] with at least one E[rror]C[orrection]C[ode], and
comprises
at least one first circuit part for the computation of the check bits or redundant bits as well as
at least one second circuit part for the single-bit error correction and/or for multi-bit error detection if applicable.

Dependent on the configuration and/or on the storage address, the mode control signal mc defines which error detection or error correction is to be used during writing operation and during reading operation.

Increasing word length or increasing word size of the data word being processed by at least one of the processing modules 10, 20 or 10′, 20′ enables to increase the information and/or the redundancy of the respective data word.

Thus, depending upon the construction of the error detection/correction circuit 100 or 100′, for the increased word length or for the increased word size the required additional one or more bits are available for storing additional information and/or for redundancy increase.

If for example the first processing module 10 or 10′ uses an 8+4-bit coding, then the concatenation of the two data words permits on the one hand a 16+8-bit data word with high redundancy, and on the other hand a 19+5-bit coding with three additional data bits being available for the application; also codings of 17+7-bits or 18+6-bits are possible if the error detection/correction circuit 100 or 100′ is designed accordingly.

FIGS. 1A and 1B concern a first exemplary application of the present invention, namely the increase of redundancy.

The example depicted in FIG. 1A uses an 8+4-bit coding wherein
the first processing part 10a of the processing module 10 is provided with an eight bit entrance Da, and
the second processing part 10b of processing module 10 is provided with an eight bit entrance Db.

Thus, the embodiment depicted in FIGS. 1A and 1B emanates from a memory area, which uses eight bit information data or payload data, and therefore stores twelve physical bits per data word or per byte. The extended data words are formed by combination of two data words each, thus 24 physical bits are available in the first data path 32 (cf. FIG. 1A).

The first processing module 10 or 10′ uses a 8+4-bit Hamming code. Fundamentally, a Hamming code is an error detection/correction code in which the difference in bit structure from character to character is particularly great, in order to maximize the probability of complete correction of the character in the event of erroneous data transmission.

Using the Hamming code in which check locations can be obtained from various parity checks, it is fundamentally possible to construct codes for correcting more than one error. In the Hamming code, only some of the information locations in the code word or data word are supplemented to give an even parity.

The second processing module 20 or 20′ uses a 16+8-bit Hamming code (cf. data path 40 in FIG. 1B) with a Hamming distance being as large as possible, wherein the Hamming distance is the count of bits different in two-bit patterns being compared.

More generally, if two ordered lists of code words or of data words are compared, the Hamming distance is the number of words which do not identically agree. Therefore, the Hamming distance of a code is a measure for the code redundancy and thus for the code ability of recognizing or even correcting errors.

The memory component or memory module 200 depicted in FIGS. 1A, 1B is designed to write and/or to read each pair of correlated data words in parallel, in order to make the extended mode possible. The memory component or memory module 200 can also be designed for serial writing and/or serial reading, for which additional schemes for buffering the data may be performed.

The second processing module 20 performs a second error detection/correction scheme, namely an enhanced error detection/correction scheme. The 16+8-coding of the enhanced error detection/correction scheme during write operation is depicted in FIG. 1A in detail:

The address bit with the lowest value a<0> differentiates between the two respective linked bytes or linked data words.

The two eight-bit bytes are extended with one or more check bits or redundant bits by means of the two processing modules 10 and 20 (cf. FIG. 1A) during the writing operation, wherein the first processing module 10 is doubly present (-->reference numerals 10a and 10b).

The first processing part 10a and the second processing part 10b are each computing the four check bits or redundant bits in accordance with the eight plus four (8+4) Hamming code to the data bytes Da and Db.

Instead, the second processing module 20 calculates the eight check bits or redundant bits in accordance with the 16+8-bit coding. Thus, FIG. 1A depicts the redundancy calculation of the first processing part 10a, of the second processing part 10b as well as of the second processing module 20.

Dependent on the selected coding mode, thus on the mode control signal mc, a 2×24-bit multiplexer mux connects either the two 12-bit bytes (cf. output signal 32 of the first data path 30) or the 24-bit word (cf. output signal 42 of the second data path 40) through to the data bus of the memory block 200. If, in case of the byte by byte coding, only a single byte is to be written, then the other byte is to be ignored by the memory block 200.

The multiplexer mux outputs a 24-bit exit Dz of the error detection/correction circuit 100. This 24-bit exit Dz is provided to the data input of the electronic memory component or electronic memory module 200.

In FIG. 1B, the enhanced error detection/correction scheme comprising a 16+8-bit coding is depicted in detail during the read operation:

During the read operation, the error detection/correction circuit 100 is provided with a 24-bit entrance Do, after being connected with the data output of the electronic memory component or electronic memory module 200.

Thereupon, during the read operation the 2×12 bits (cf. data path 30a, 30b in FIG. 1B), with the bits belonging together and being read by the memory block 200, are evaluated and corrected with the first processing part 10a and with the second processing part 10b, i.e.
renewed computation of the parity bits from the eight data bits,
generation of the syndrome word from comparison of the computed and stored four-bit parity, and
appropriate correction of a wrong bit if necessary

take place.

Additionally, the 24 read bits (cf. data path 40 in FIG. 1B) are evaluated by the extended error detection/correction scheme, i.e. computation of the eight-bit parity and of the corresponding syndrome word takes place.

25 values of the syndrome word correspond to the condition “no error” or to the condition “one-bit-error” each, which error is corrected accordingly. All remaining 231 syndrome words are interpreted as reference to invalid data and indicated for example as a set status bit DS.

Consequently, in FIG. 1B the syndrome calculation and the data correction of the first processing part 10a of the first processing module 10, of the second processing part 10b of the first processing module 10, as well as of the second processing module 20 is depicted.

The check signal mc decides whether the result of the byte by byte correction or of the word by word correction is to be supplied as valid original data or as valid raw data; the multiplexer mux passes the corresponding data through.

After processing the read operation three exits Dx, Dy, Ds of the error detection/correction circuit 100 result. More particularly, a first eight-bit exit Dx, a second eight-bit exit Dy and a status information signal Ds are provided.

In this context, the status information signal Ds comprises information about data integrity during reading operation in extended mode in case of increasing redundancy, for example status signals indicating whether data can be read in unaltered way, have to be corrected and can be corrected or are uncorrectably wrong.

FIGS. 2A, 2B concern a second exemplary application of the present invention, namely the storage of additional information, for example of status bits.

In FIG. 2A, the write operation in case of a 19+5-bit coding of the enhanced error detection/correction scheme is depicted in detail:

FIG. 2A shows in analogy to FIG. 1A the procedure for storing additional information; as in the first application (cf. FIGS. 1A, 1B), the first processing part 10a′ of the first processing module 10′ and the second processing part 10b′ of the first processing module 10′ compute the respectively four check bits or redundant bits to both data bytes Da, Db.

The second processing module 20′ for the extended mode computes to the delivered data bytes Da, Db as well as to additional three-bit data Dc the five redundant bits (cf. data path 40′ in FIG. 2A).

The multiplexer mux behaves as described above.

In FIG. 2B, the read operation in case of a 19+5-bit coding of the enhanced error detection/correction scheme is depicted in detail:

The read operation is essentially identical to the first application (cf. FIGS. 1A, 1B); however, the second processing module 20′ computes in this example only a five-bit parity and accordingly a five-bit syndrome word.

In exchange, the second processing module 20′ provides nineteen information bits or payload data bits at the exit (cf. output signal 42′ of second data path 40′ in FIG. 2B); of these nineteen information bits or payload data bits, 2×8 bits are available as “normal” data and three bits are available as additional information.

After processing the read operation, three exits Dx, Dy, Df of the error detection/correction circuit 100′ result. More particularly, a first eight-bit exit Dx, a second eight-bit exit Dy and a three-bit exit Df are provided. The three-bit exit Df is assigned to the extended mode with storage of additional information instead of redundancy increase.

### LIST OF REFERENCE NUMERALS

100 error detection/correction circuit (first embodiment; cf. FIGS. 1A, 1B)
100′ error detection/correction circuit (second embodiment; cf. FIGS. 2A, 2B)
10 first processing module of error detection/correction circuit 100 (first embodiment; cf. FIGS. 1A, 1B)
10a first processing part of first processing module 10 performing redundancy calculation (writing operation) and/or performing syndrome calculation and data correction (reading operation)
10b second processing part of first processing module 10 performing redundancy calculation (writing operation) and/or performing syndrome calculation and data correction (reading operation)
10′ first processing module of error detection/correction circuit 100′ (second embodiment; cf. FIGS. 2A, 2B)
10a′ first processing part of first processing module 10′ performing redundancy calculation (writing operation) and/or performing syndrome calculation and data correction (reading operation)
10b′ second processing part of first processing module 10′ performing redundancy calculation (writing operation) and/or performing syndrome calculation and data correction (reading operation)
20 second processing module of error detection/correction circuit 100 performing redundancy calculation (writing operation) and/or performing syndrome calculation and data correction (reading operation) (first embodiment; cf. FIGS. 1A, 1B)
20′ second processing module of error detection/correction circuit 100′ performing redundancy calculation (writing operation) and/or performing syndrome calculation and data correction (reading operation) (second embodiment; cf. FIGS. 2A, 2B)
30 first data path being assigned to first processing module 10 (first embodiment; cf. FIGS. 1A, 1B)
30′ first data path being assigned to first processing module 10′ (second embodiment; cf. FIGS. 2A, 2B)
30a first part of first data path 30 being assigned to first processing part 10a
30a′ first part of first data path 30′ being assigned to first processing part 10a′
30b second part of first data path 30 being assigned to second processing part 10b
30b′ second part of first datapath 30′ being assigned to second processing part 10b′
32 output signal of first data path 30 (first embodiment; cf. FIGS. 1A, 1B)
32′ output signal of first data path 30′ (second embodiment; cf. FIGS. 2A, 2B)
40 second data path being assigned to second processing module 20 (first embodiment; cf. FIGS. 1A, 1B)
40′ second data path being assigned to second processing module 20′ (second embodiment; cf. FIGS. 2A, 2B)
42 output signal of second data path 40 (first embodiment; cf. FIGS. 1A, 1B)
42′ output signal of second data path 40′ (second embodiment; cf. FIGS. 2A, 2B)
200 electronic memory component or electronic memory module, in particular electronic memory block or electronic memory unit (first embodiment; cf. FIGS. 1A, 1B)
200′ electronic memory component or electronic memory module, in particular electronic memory block or electronic memory unit (second embodiment; cf. FIGS. 2A, 2B)
Da eight-bit entrance of error detection/correction circuit 100, 100′ being assigned to first part 30a, 30a′ of first data path 30, 30′ during writing operation (byte A)
   Db eight-bit entrance of error detection/correction circuit 100′ being assigned to second part 30b, 30b′ of first data path 30, 30′ during writing operation (byte B)
Dc three-bit entrance of error detection/correction circuit 100, 100′ being assigned to second data path 40′ during memory operation with storage of additional information instead of redundancy increase
Df three-bit exit of error detection/correction circuit 100′ during reading operation in extended mode with storage of additional information instead of redundancy increase (second embodiment; cf. FIGS. 2A, 2B)
Do twenty-four-bit entrance of error detection/correction circuit 100, 100′ during reading operation, to be connected with data output of electronic memory component or electronic memory module 200, 200′
Ds status information about data integrity during reading operation in extended mode during redundancy increase, for example status signals, indicating whether data can be read unaltered, have to be corrected and can be corrected or are uncorrectably wrong
Dx first eight-bit exit of error detection/correction circuit 100, 100′ during reading operation (byte A)
Dy second eight-bit exit of error detection/correction circuit 100, 100′ during reading operation (byte B)
Dz 24-bit exit of error detection/correction circuit 100, 100′, to be connected with data input of electronic memory component or electronic memory module 200, 200′
mc check signal for error correction mode selection, in particular mode control signal (normal operation or extended operation)
mux multiplexer module or multiplexer unit

1. An error detection/correction circuit for detecting and/or for correcting at least one error of at least one data word, said data word comprising:
information in the form of at least one information bit or at least one payload data bit, and
redundancy in the form of at least one check bit or at least one redundant bit,
the error detection/correction circuit comprising at least one first processing module
being assigned to at least one first data path, and
being designed for performing at least one first error detection/correction scheme, characterized by
at least one second processing module
being assigned to at least one second data path,
being designed for performing at least one second error detection/correction scheme, and
being designed for increasing the information and/or the redundancy, in particular
for increasing the number of the one or more information bits or of the one or more payload data bits and/or
for increasing the number of the one or more check bits or of the one or more redundant bits,
of the respective data word being transmitted through the second data path.

2. The error detection/correction circuit according to claim 1, characterized in that the first processing module, in particular;
at least one first processing part being assigned to at least one first part of the first data path and
at least one second processing part being assigned to at least one second part of the first data path, and the second processing module are designed
for performing redundancy calculation, in particular for supplementing the respective data word being transmitted through the respective data path with the one or more check bits or with the one or more redundant bits, during at least one writing operation, and/or
for performing error detection, in particular for calculating at least one syndrome word, and/or for performing error correction, in particular for correcting the respective data word being transmitted through the respective data path, during at least one reading operation.

3. The error detection/correction circuit according to claim 1, characterized in that the one or more data words being transmitted through the second data path can have a different, in particular an increased, word length or word size in comparison to the one or more data words being transmitted through the first data path, in particular that the one or more data words being transmitted through the second data path can be correlated to the one or more data words being transmitted through the first data path when transmitted roughly in parallel and/or roughly at the same time.

4. An electronic memory component or memory module for processing at least one data element, said data element comprising at least two data words, wherein each data word is assigned to at least one memory area, said memory area being in particular assigned to at least one address range, characterized by at least one error detection/correction circuit according to claim 1 for enabling an, in particular variable, selection of a suitable word length or word size for the respective memory area.

5. The memory component or memory module according to claim 4, characterized by being designed for performing at least one writing operation and/or at least one reading operation of the first processing module as well as of the second processing module in parallel and/or in serial.

6. The memory component or memory module according to claim 4, characterized by:
at least one data bus,
at least one multiplexer module or multiplexer unit for interconnecting the first processing module and the second processing module with the data bus, in particular for providing the data bus
with at least one output signal of the first data path and/or
with at least one output signal of the second data path,
depending on at least one signal, in particular on at least one mode control signal, and/or
the memory component or memory module being configured as
at least one E[rasable]P[rogrammable]R[ead]O[nly]M[emory],
at least one
E[lectrically]E[rasable]P[rogrammable]R[ead]O[nly]M[emory],
at least one flash memory,
at least one R[ead]O[nly]M[emory] or
at least one R[andom]A[ccess]M[emory].

7. A method for detecting and/or for correcting at least one error of at least one data word, said data word comprising:
information in the form of at least one information bit or at least one payload data bit, and
redundancy in the form of at least one check bit or at least one redundant bit, characterized by
performing at least one first error correction scheme being assigned to at least one first data path, and
performing at least one second error correction scheme
being assigned to at least one second data path, and
being designed for increasing the information and/or the redundancy, in particular
for increasing the number of the one or more information bits or of the one or more payload data bits and/or
for increasing the number of the one or more check bits or of the one or more redundant bits,
of the respective data word being transmitted through the second data path.

8. The method according to claim 7, characterized in that the first error correction scheme and the second error correction scheme respectively comprise the steps of:
performing redundancy calculation, in particular supplementing the respective data word being transmitted with the one or more check bits or with the one or more redundant bits, during at least one writing operation, and/or
performing error detection, in particular calculating at least one syndrome word, and/or performing error correction, in particular correcting the respective data word being transmitted, during at least one reading operation.

9. The method according to claim 7, characterized in that the second error correction scheme is designed for supplementing a variable and/or individual number of check bits or redundant bits to the respective data word by performing the step of redundancy calculation, the number of supplemented check bits or redundant bits in particular depending;
on the word size, in particular on the logical word length, of the respective data word and/or
on the application of the respective data word.

10. Use of at least one error detection/correction circuit according to claim 1 and/or of at least one electronic memory component or memory module when processing at least one security-relevant or safety-critical application, in particular in at least one chip card or smart card, for example in at least one embedded security controller.
